(19) United States
(12) Patent Application Publication
(10) Pub. No.: US 2009/0123874 A1
(43) Pub. Date: May 14, 2009

(54) EXPOSURE METHOD, EXPOSURE APPARATUS, AND METHOD FOR MANUFACTURING DEVICE

(76) Inventor: Tadashi NAGAYAMA, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/247,892

(22) Filed: Oct. 8, 2008

Related U.S. Application Data
(60) Provisional application No. 60/996,379, filed on Nov. 14, 2007.

(51) Int. Cl. G03F 7/20; G03B 27/32; G03B 27/42

(52) U.S. Cl. 430/311; 355/77; 355/53

(57) ABSTRACT

An exposure apparatus for efficiently exposing patterns onto corresponding regions of a substrate. The apparatus includes a first wafer stage, a second wafer stage, an alignment sensor which detects marks of wafers on the wafer stages, a projection optical system which irradiates a first region of a wafer with first exposure light, and an imperfect shot region exposure system which irradiates a second region of a wafer that differs from the first region with second exposure light. The imperfect shot region exposure system irradiates the second region of a wafer held on the second wafer stage with the second exposure light.

### CROSS-REFERENCE TO RELATED APPLICATIONS

This application claims the benefit of U.S. Provisional Application No. 60/996,379, filed on Nov. 14, 2007.

### BACKGROUND

The present disclosure relates to an exposure technique for exposing a plurality of different regions on a substrate that is, for example, applicable when exposing onto an imperfect shot region of a substrate a pattern that is to be exposed onto a perfect shot region of the substrate. The present disclosure further relates to a technique for manufacturing a device using the exposure technique.

In a lithography process for manufacturing various types of devices (electronic devices and micro-devices), for example, semiconductor devices, liquid crystal display devices, and the like, an exposure apparatus such as a batch exposure type projection exposure apparatus like a stepper and the like or a scanning exposure type projection exposure apparatus (scanning type exposure apparatus) like a scanning stepper or the like is used to transfer a pattern of a reticle (or photomask etc.) onto a wafer (or glass plate etc.) to which resist is applied.

A wafer exposed by such an exposure apparatus includes a peripheral portion having imperfect shot regions arranged outside an effective exposure field. Such imperfect shot regions cannot be used for devices and therefore should not be exposed. However, a chemical and mechanical polishing (CMP) process is nowadays employed to smooth the surface of a wafer on which a pattern is formed. Therefore, when employing the CMP process, the pattern on the wafer having the same level (or either one of cyclicality and pattern density) as the central portion of the wafer must be formed on the peripheral portion of the wafer. Here, if the L & S (Line and Space) pattern is formed on the wafer in order to explain easily, the level means the difference in level between the surface of line and the surface of space. The cyclicality relates to the pitch of L & S pattern. The pattern density relates to the ratio between the width of line and the width of space. In such a case, exposure of a reticle pattern onto such imperfect shot regions lowers the throughput.

Accordingly, a simple exposure optical system arranged, for example, in a development device includes an exposure unit that exposes only imperfect shot regions in the peripheral portion of a wafer has been proposed (for example, refer to patent document 1). Further, an exposure apparatus that includes an auxiliary pattern plate arranged on a reticle stage near a reticle to efficiently expose imperfect shot regions through a pattern of the auxiliary pattern plate has been proposed (for example, refer to patent document 2).

### [Patent Document 1] Japanese Laid-Open Patent Publication No. 5-259069

### [Patent Document 2] Japanese Laid-Open Patent Publication No. 2006-278820

### SUMMARY

The prior art exposure unit for exposing imperfect shot regions does not include a high accuracy alignment mechanism or the like. Thus, it is difficult to accurately expose only the imperfect shot regions of a wafer. In this aspect, if high accuracy alignment and focus position measurement were to be performed from the beginning to expose the imperfect shot regions, the throughput may decrease.

In the exposure apparatus that arranges the auxiliary pattern on the reticle stage, perfect shot regions cannot be exposed when the imperfect shot regions are exposed. Therefore, the level of improvement in throughout is small.

The present disclosure relates to an exposure technique and a device manufacturing technique that efficiently exposes patterns onto corresponding regions (for example, portion including perfect shot regions and portion including imperfect shot region) of a substrate, such as a wafer.

The structure of an embodiment of the present invention will now be discussed using reference characters. However, the present invention is not limited to this embodiment.

In an exposure method according to one embodiment of the present invention which exposes a plurality of regions including different first region (65D) and second region (65ND) of a substrate. The exposure method includes a first block (steps 213, 104) of exposing a first region of a first substrate (W1), which is held on a first substrate movable holder (WST1) that moves along a two-dimensional plane, with a first optical system PL), and, in parallel, detecting a predetermined mark (WMS1, WMS2) from a plurality of predetermined marks on a second substrate movable holder (WST2) that moves along the two-dimensional plane or on a second substrate (W2) held by the second substrate movable holder; a second block (steps 105 to 108) of exposing a second region of the second substrate, which is held on the second substrate movable holder, with a second optical system (40A to 40D) based on the detection result of the predetermined mark, and, in parallel, detecting a mark (WM) excluding the predetermined mark from the plurality of marks; and a third block (step 113) of exposing a first region of the second substrate, which is held on the second substrate movable holder, with the first optical system based on the detection results of the plurality of marks.

In an exposure apparatus according to one embodiment of the present invention which exposes a plurality of regions in a substrate, the exposure apparatus includes a first substrate movable holder (WST1) which holds a substrate and is movable along a two-dimensional plane. A second substrate movable holder (WST2) holds a substrate and is movable along the two-dimensional plane. An alignment system (26) detects at least either one of marks on the two substrate movable holders and marks on the substrates held by the two substrate movable holders. A first optical system (PL) irradiates a first region (65D) of a substrate with first exposure light. A second optical system irradiates a second region (65ND) of a substrate that differs from the first region with second exposure light. The alignment system detects marks on the second substrate movable holder or the second substrate held, which is held by the second substrate movable holder when the first optical system irradiates the first substrate, which is held by the first substrate movable holder, with the first exposure light. The second optical system irradiates the second region of the second substrate, which is held by the second substrate movable holder, with the second exposure light when the alignment system is detecting the mark.

In one embodiment of the present invention, the exposure of a first region (for example, region including perfect shot regions) of a first substrate on a first substrate movable holder is performed substantially parallel to the exposure of a second region (for example, portion including perfect shot regions) of a second substrate on a second substrate movable holder. Thus, patterns corresponding to the first and second regions can be efficiently exposed. Further, the detection of a mark (mark detection operation of second block) with an alignment system for exposing the first region of the second substrate is performed substantially parallel to the exposure of the second region of the substrate. This further improves throughput of the exposure block.

### BRIEF DESCRIPTION OF THE DRAWINGS

FIG. 1 is a schematic diagram of an exposure apparatus according to one embodiment of the present invention;

FIG. 2 is a plan view showing wafer stages WST1 and WST2 on a wafer base WB1 of FIG. 1;

FIG. 3(A) is a diagram showing the structure of an aerial image measurement system 55A of FIG. 2, and FIG. 3(B) is a diagram showing another example of an aerial image measurement system;

FIG. 4(A) is a plan view showing one example of a shot region map of the wafer W2 of FIG. 1, FIG. 4(B) is an enlarged view showing a pattern exposed by the projection optical system PL of FIG. 1, FIG. 4(C) is an enlarged view showing a pattern exposed by an exposure region 46A of FIG. 4(A), and FIG. 4(D) is an enlarged view showing a pattern exposed by an exposure region 46C of FIG. 4(A);

FIG. 5 is a plan view showing the exposure of imperfect shot regions in the wafer W2 by the exposure regions 46A and 46B;

FIG. 6 is a plan view showing the exposure of imperfect shot regions in the wafer W2 by the exposure regions 46C and 46D;

FIGS. 7(A) and 7(B) show a flowchart showing one example of an exposure operation performed by the exposure apparatus 100 of FIG. 1;

FIG. 8 is a flowchart partially showing operations performed in parallel by two wafer stages of FIG. 1; and

FIG. 9 is a plan view showing a state in which a second wafer stage WST2 is moved to under a projection optical system PL and a first wafer stage WST1 is moved to under an alignment sensor 26.

### DETAILED DESCRIPTION OF THE PREFERRED EMBODIMENTS

One example of a preferred embodiment according to the present invention will now be described with reference to the drawings.

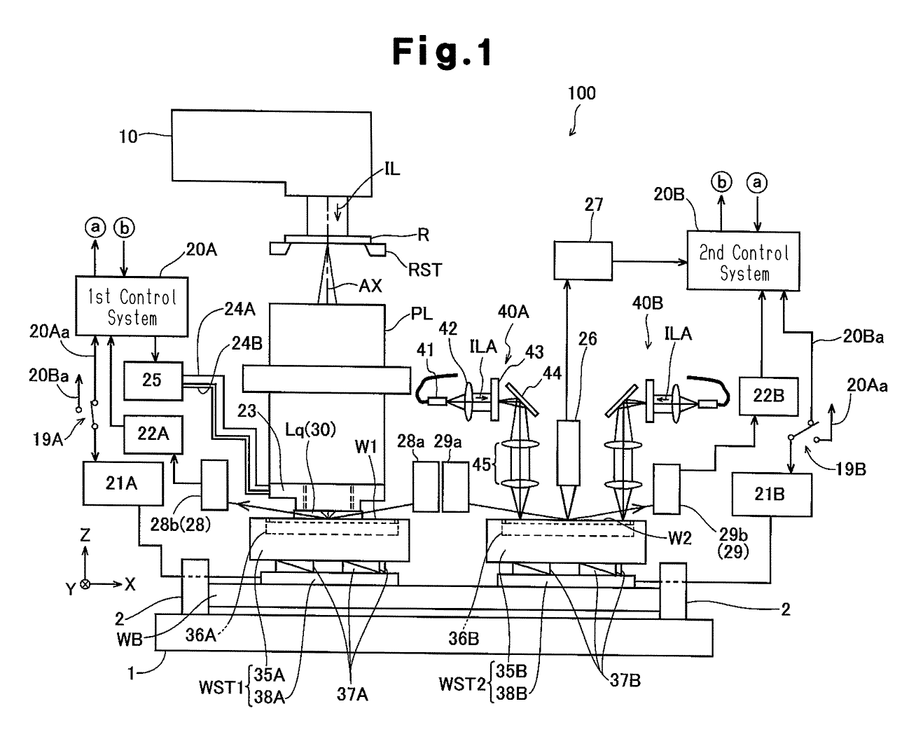

FIG. 1 is a schematic diagram showing an exposure apparatus 100 of the present embodiment. The exposure apparatus 100 is a projection exposure apparatus of a scanning exposure type that includes a scanning stepper (scanner) and performs exposure through liquid immersion.

In FIG. 1, the exposure apparatus 100 includes an illumination system 10, a reticle stage RST, a projection optical system PL, a first wafer stage WST1, and a first control system 20A. The illumination system 10, which includes a light source and an illumination optical system, illuminates a reticle R (mask) with exposure light IL (illumination light used for exposure) serving as an exposure beam. The reticle stage RST holds and moves the reticle R. The projection optical system PL exposes a region on a wafer (in FIG. 1, wafer W1), which serves as a substrate, including a device region 65D formed by perfect shot regions with the exposure light IL through the reticle R. The first wafer stage WST1 holds and moves the wafer W1. The first control system 20A is formed by a computer that centrally controls the exposure operation performed by the projection optical system 20A.

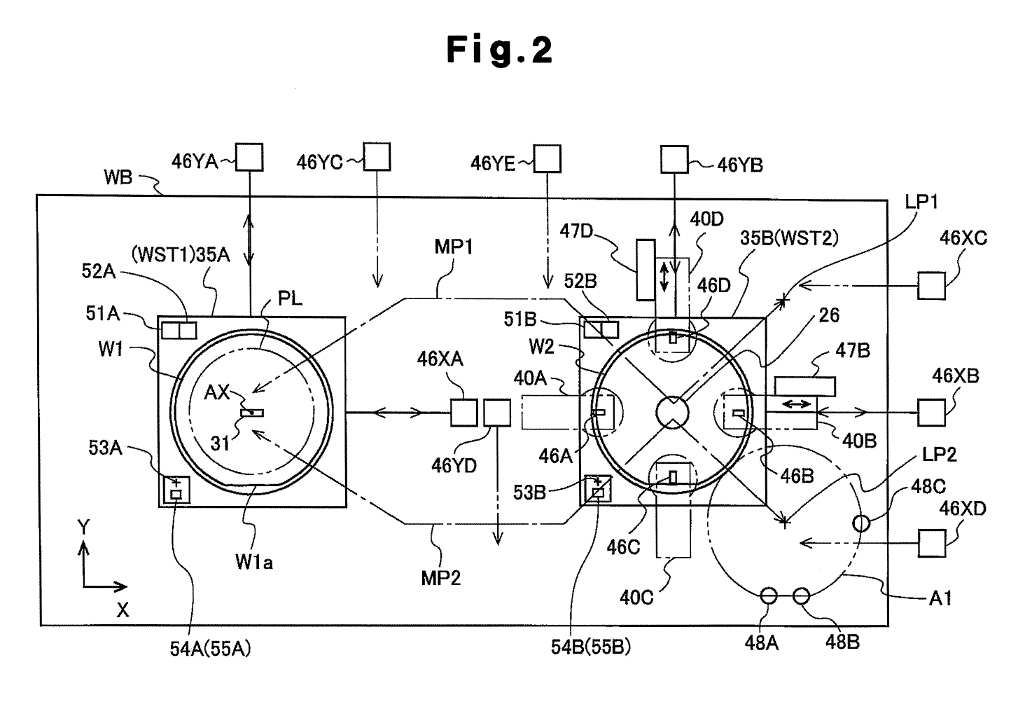

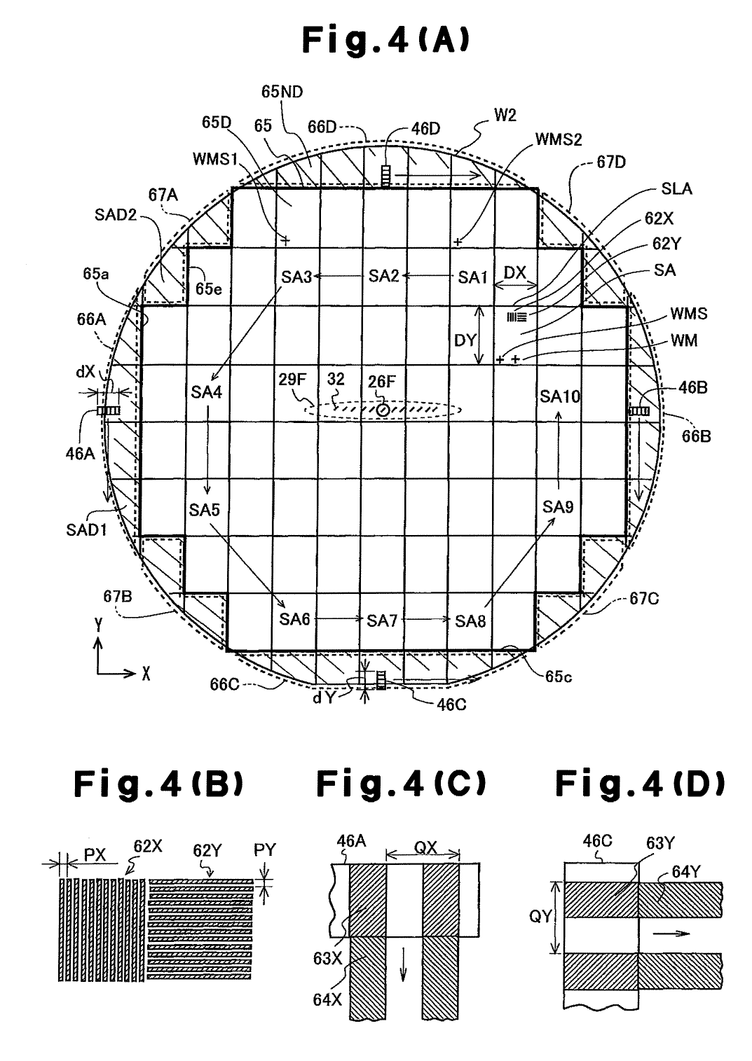

Further, the exposure apparatus 100 includes imperfect shot region exposure systems 40A, 40B, 40C, and 40D (refer to FIG. 2), a second wafer stage WST2, an alignment sensor 26, a second control system 20B, various types of drive systems, and the like. The imperfect shot region exposure systems 40A, 40B, 40C, and 40D each expose at least part of a non-device region 65ND (refer to FIG. 4(A)) formed by imperfect short regions of a wafer (in FIG. 1, wafer W2) with exposure light ILA. The second wafer stage WST2 holds and moves the wafer W2. The alignment sensor 26 detects reference marks on the wafer stages WST1 and WST2 and marks (alignment marks) on the wafer stages WST1 and WST2. The second control system 20B is formed by a computer that centrally controls the alignment performed with the alignment sensor 26 and the exposure operations performed by the imperfect shot region exposure systems 40A to 40D. The first control system 20A and the second control system 20B exchange information such as measurement information and operation timing information.

The two wafer stages WST1 and WST2 of the exposure apparatus 100 have the same structures. Thus, the layout of FIG. 1 may be reversed so that the wafer on the second wafer stage WST2 is exposed by the projection optical system PL and, at the same time, the wafer on the first wafer stage WST1 is exposed by the imperfect shot region exposure systems 40A to 40D. In the description hereafter, the Z axis is parallel to the optical axis AX of the projection optical system PL. Further, along a plane orthogonal to the Z axis (in the present embodiment, a generally horizontal plane), the X axis extends parallel to the plane of FIG. 1, and the Y axis extends orthogonal to the plane of FIG. 1. During scanning exposure, the direction in which the reticle R and the wafer (wafer W1 etc.) are scanned is the Y direction (direction parallel to the Y axis).

In FIG. 1, the illumination optical system in the illumination system 10 includes a uniform illuminance optical system formed by an optical integrator (diffraction optical device, fly eye's lens, etc.), a relay lens system, a reticle blind (field stop), a condenser lens system, and the like, as disclosed in, for example, Japanese Laid-Open Patent Publication No. 2001-313250. The illumination system 10 illuminates a slit-shaped illumination region formed on the reticle R by the reticle blind with a substantially uniform illuminance distribution. As the exposure light IL, for example, ArF excimer laser light (wavelength, 193 nm) of which oscillation wavelength has been narrowed to reduce color aberration can be used. Further, as the exposure light IL, KrF excimer laser light (wavelength, 193 nm), a harmonic wave of a solid laser (YAG laser, semiconductor laser, etc.), or emission lines and the like of a mercury lamp may be used.

The reticle stage RST, which holds the reticle R, is placed on a guide plane of a reticle base (not shown) and driven at a designated scanning speed in the Y direction by a reticle stage drive unit (not shown), which includes a linear motor etc. The reticle stage RST is also finely driven in the X direction, Y direction, and rotation direction (θZ) about an axis parallel to the Z direction. The position of the guide plane on the reticle stage RST is constantly measured by a reticle interferometer (not shown) having a resolution of, for example, 0.5 to 0.1 nm. Based on the position information, a reticle stage control unit in the first control system 20A controls the position and speed of the reticle stage RST with the reticle stage drive unit.

In FIG. 1, the projection optical system PL is, for example, double telecentric and has a predetermined magnification (e.g., ¼ or ⅕ times). When the illumination field of the reticle R is illuminated with the exposure light IL from the illumination system 10, the projection optical system PL forms an image of a circuit pattern of the illumination field on an exposure region 31 (refer to FIG. 2), which is elongated in the X direction and located in one shot region of the wafer W, with the exposure light IL that passes through the reticle R. The wafers W1 and W2 are obtained by applying resist (photosensitive agent), which is photosensitive to the exposure light IL, to the surface of a base material having a diameter of 200 to 300 mm, such as a semiconductor (silicon etc.) or silicon on insulator (SOI). A notch W1a (refer to FIG. 2), which is an orientation flat for detecting a rotational angle, is formed on each of the wafers W1 and W2. The projection optical system PL is a catadioptric system including a refractive optical system or mirror and lens. The reticle base and the projection optical system are supported on a frame (not shown) by means of a damping mechanism.

The alignment sensor 26 is spaced from the projection optical system PL in the +X direction. The alignment sensor 26 includes an illumination system, which irradiates a detected mark with illumination light having a relatively long wavelength band, and a variable magnification light receiving system, which captures an enlarged image of the detected mark. Further, the alignment sensor 26 employs a field image alignment (FIA) technique for image-processing the captured image and obtaining the position of the detected mark. The detection signal of the alignment sensor 26 is provided to the second control system 20B via a signal processing system 27. The FIA alignment sensor is disclosed in, for example, Japanese Laid-Open Patent Publication No. 7-183186.

In FIG. 1, a generally ring-shaped nozzle unit 23, which is supported by a frame (not shown), surrounds the distal portion of an optical member (not shown) of the projection optical system PL that is located closest to an image plane (wafer side). A liquid supply passage and liquid recovery passage in the nozzle unit 23 are respectively connected via a supply pipe 24A and a recovery pipe 24B to a liquid supply-recovery device 25. Under the control of the first control system 20A, the liquid supply-recovery device 25 supplies a liquid immersion region 30 formed between the distal end of the projection optical system PL and a wafer with liquid Lq and recovers the liquid Lq using a local immersion technique.

As one example of the liquid Lq, ultrapure water (hereinafter, simply referred to as water) through which exposure light IL passes (here, ArF excimer laser light) is used. The refractive index of the water with respect to the exposure light IL is approximately 1.44. Therefore, the wavelength of the exposure light IL, which exposes a wafer, is shortened to approximately 134 nm (=193 nm×1/n). This increases the resolution and focal depth. Decalin, which is a liquid having a high refractive index, may also be used as the liquid.

The resist applied to the wafers W1 and W2 may be a liquid repellant resist that repels the liquid, and a protective top coat is applied to the resist when necessary. Further, a liquid repellant coating, which repels the liquid Lq is applied to regions surrounding the wafers W1 and W2 on the upper surfaces of the wafer stages WST1 and WST2 (excluding portions at which reference marks etc, which will be described later, are formed).

The present embodiment includes the ring-shaped nozzle unit 23. However, the present embodiment is not limited in such a manner and a liquid supply-recovery system may include a plurality of nozzle members for supplying liquid and a plurality of nozzle members for recovering the liquid as disclosed in International Publication No. 99/49504.

In FIG. 1, a plurality of air bearings support the wafer stages WST1 and WST2 in a levitated state and in a non-contact manner along a guide plane (XY plane) that is orthogonal to a wafer base WB arranged horizontally under the projection optical system PL. The wafer base WB is supported on a floor member 1 by a plurality of damping bases 2. The wafer stages WST1 and WST2 vacuum-attracts (or electrostatically attracts) the wafers W1 and W2 with wafer holders 36A and 36B, respectively.

The first wafer stage WST1 includes an XY stage 38A; which is driven by a drive unit (not shown), such as a linear motor or a planar motor, on the wafer base WB in the X direction, Y direction, and θZ direction; a Z-leveling stage 35A; and three actuators 37A (includes, for example, a voice coil motor), of which positions in the Z direction are variable and which are arranged on the XY stage 38A to support the Z-leveling stage 35A. The three actuators 37A are independently driven in the Z direction to perform focusing on an image plane of the projection optical system PL or an observation plane of the alignment sensor 26. Thus, the position of the Z-leveling stage 35A in the Z direction (focus position) relative to the XY stage 38A and inclination angles θX and θY about axes parallel to the X axis and Y axis are controllable.

The XY stage 38A of FIG. 1 is driven in the XY plane, and a signal line of a wafer stage control unit 21A, which drives the actuators 37A, is selectively connected by a switch unit 19A to a signal line 20Aa of the first control system 20A and a signal line 20Ba of the second control system 20B.

In the same manner as the first wafer stage WST1, the second wafer stage WST2 includes an XY stage 38B, which is driven on the wafer base WB, a Z-leveling stage 35B, which holds the wafer W2, and three actuators 37B, which drive the Z-leveling stage 35B in the Z direction. Further, a signal line of a wafer stage control unit 21B, which drives the second wafer stage WST2, is selectively connected by a switch unit 19B to the signal line 20Aa and the signal line 20Ba. The switching of the switch units 19A and 19B are controlled by the first control system 20A. The wafer stages WST1 and WST2 are controlled by the first control system 20A when located under the projection optical system PL and controlled by the second control system 20B when located under the alignment sensor 26.

To drive the wafer stage WST1 or WST2, the control systems 20A and 20B measure position information on the guide plane of the wafer base WB for the wafer stage WST1 or WST2 and measures distribution information of the focus position (position in the Z direction) of the wafer W1 or W2 on the wafer stage WST1 or WST2.

A diagonal incidence type multiple point auto-focus sensor (hereinafter, referred to as the AF system) 28 is supported by a column (not shown) to measure focus positions of a plurality of measurement points on a detected region. The AF system 28 includes at the lower plane of the projection optical system PL a light emitting system 28a, which diagonally projects a plurality of slit images (detection patterns) onto a detected region including an exposure region of the projection optical system PL and regions near the exposure region, and a light receiving system 28b, which receives reflection light from the detected region. The light receiving system 28b of the AF system 28 provides a detection signal to a signal processing unit 22A, and the signal processing unit 22A obtains a defocus amount from an image plane of the focus position of each measurement point in the detected region and provides the first control system 20A with distribution information of the obtained defocus amount (focus position information). The detailed structure of a diagonal incidence type multiple point AF system is disclosed in, for example, U.S. Pat. No. 5,633,721 and Japanese Laid-Open Patent Publication No. 2007-48819.

Similarly, a diagonal incidence type multiple point AF system 29, which is supported by a column (not shown), includes a light emitting system 29a and a light receiving system 29b at the lower plane of the alignment sensor 26 in the same manner as the AF system 28 and projects a plurality of slit images 32 onto an elongated detected region 29F (refer to FIG. 4(A)), which includes a field 26F of the alignment sensor 26. The light receiving system 29b of the AF system 29 provides a detection signal to a signal processing unit 22B, and the signal processing unit 22B obtains a defocus amount from a predetermined reference plane (for example, a plane including a best focus plane of the alignment sensor 26) of the focus position of each measurement point in the detected region and provides the second control system 20B with distribution information of the obtained defocus amount (focus position information).

FIG. 2 is a plan view showing the wafer stages WST1 and WST2 on the wafer base WB of FIG. 1. In FIG. 2, the side surfaces of the Z-leveling stages 35A and 35B of the wafer stages WST1 and WST2 in the X direction and Y direction are mirror-surface-processed so that they can be used as reflection surfaces of movable mirrors. Rod-shaped movable mirrors may be fixed to the side surfaces.

A frame supports Y axis laser interferometers 46YA and 46YB, which emit a plurality of measurement laser beams on a reflection surface of the stage that is subject to measurement along the optical axis AX of the projection optical system PL and through the center of the view field of the alignment sensor 26 parallel to the Y axis, and X axis laser interferometers 46XA and 46XB, which emit a plurality of measurement laser beams on another reflection surface of the stage along the optical axis AX of the projection optical system PL and through the center of the view field parallel to the X axis.

In the state of FIG. 2, the laser interferometers 46XA and 46YA measure the position of the first wafer stage WST1 (Z-leveling stage 35A) in at least the X direction, Y direction, and θZ direction and provide the second control system 20B of FIG. 1 with the measurement information. In FIG. 2, in one example, the first wafer stage WST1 moves along a path MP1, which is bent toward the +Y direction side of the wafer base WB, between a position below the projection optical system PL and a position below the alignment sensor 26. Further, the second wafer stage WST2 moves along a path MP2, which is bent toward the −Y direction side of the wafer base WB, between a position below the projection optical system PL and a position below the alignment sensor 26.

To continuously measure the Y coordinates and X coordinates of the wafer stages WST1 and WST2, which move along the paths MP1 and MP2, Y axis laser interferometers 46YC, 46YD, and 46YE are arranged between the Y axis laser interferometers 46YA and 46YB. Further, X axis laser interferometers 46XC and 46XD are arranged so as to sandwich the X axis laser interferometer 46XB in the Y direction. The measurement resolutions of the laser interferometers 46XA to 46XD and 46YA to 46YE are each, for example, 0.5 to 0.1 nm. As one example, the measurement values of the laser interferometers 46XC, 46YC, and 46YD are provided to the first control system 20A of FIG. 1, and the measurement values of the laser interferometers 46XD and 46YE are provided to the second control system 20B.

Further, as one example, wafer loading and unloading positions LP1 and LP2 respectively set for the wafer stages WST1 and WST2 are located on the +X direction end at the +Y direction and −Y direction ends of the wafer base WB. Alternatively, for example, position LP1 may be set as a common wafer loading position for the wafer stages WST1 and WST2, and position LP2 may be set as a common wafer unloading position for the wafer stages WST1 and WST2.

In the present embodiment, a frame (not shown) supports three image-processing type pre-alignment sensors (hereinafter referred to as PA sensors) 48A, 48B, and 48C to detect a profile A1 of a wafer W2 that is located at the position LP2 of FIG. 2. The detection results of the PA sensors 48A to 48C are provided to the second control system 20B of FIG. 1. In the same manner, three PA sensors (not shown) detect the profile of a wafer located at position LP1. If, for example, a pre-alignment sensor is arranged in a wafer loader system (not shown), the PA sensors 48A to 48C and the like may be eliminated.

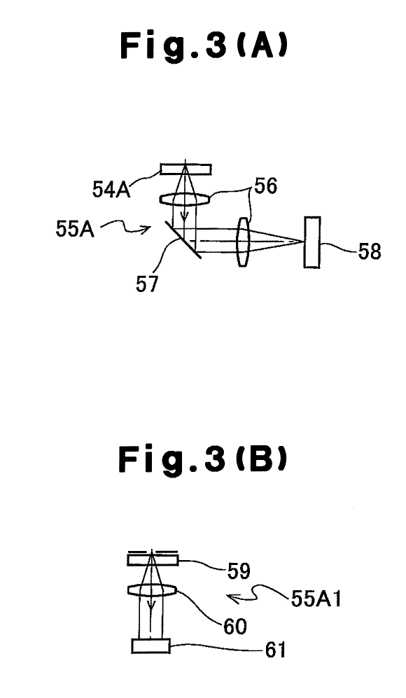

In FIG. 2, an illuminance variation sensor 51A and an illuminance sensor 52A, which respectively measure the illumination level and illumination amount of the exposure light, and a reference member, which includes a reference mark 53A and a light receiving window 54A, are arranged at the vicinity of the wafer W1 on the upper surface of the first wafer stage WST1. An aerial image measurement system 55A is arranged in the Z-leveling stage 35A on the bottom surface of the light receiving window 54A. Referring to FIG. 3(A), the aerial image measurement system 55A is of an imaging type including an imaging system 56, which images the exposure light IL that passes through the light receiving window 54A, a mirror 57, which deflects the exposure light IL, and a CCD type or CMOS type two-dimensional imaging device 58, which captures an image of the exposure light IL. The illuminance variation sensor 51A, the illuminance sensor 52A, and the imaging device provide the first control system 20A with detection signals via a signal processing system (not shown).

As one example, an index mark (not shown), which has a predetermined relationship with the reference mark 53A, is formed on the upper surface of the light receiving window 54A. The aerial image measurement system measures the positional relationship between the index mark and the image of a reticle mark formed on the reticle R by the projection optical system PL to perform reticle alignment and baseline measurement. As shown in FIG. 3(B), instead of the image capturing type aerial image measurement system 55A, a scanning type aerial image measurement system 55A1, which includes a slit plate 59 having a slit, a light converging lens 60, and a light receiving device 61 such as a photodiode, may be used. The aerial image measurement system 55A1 relatively scans the slit of the slit plate 59 and the image of a detected mark to detect the image position of the detected mark.

In FIG. 2, an illuminance variation sensor 51B, an illuminance sensor 52B, and a reference member, which includes a reference mark 53B and a light receiving window 54B, are arranged at the vicinity of the wafer W2 on the upper surface of the second wafer stage WST2. An aerial image measurement system 55B, which is identical to the aerial image measurement system 55A, is arranged on the bottom surface of the light receiving window 54B.

Returning to FIG. 1, a frame (not shown) supports two imperfect shot region exposure systems 40A and 40B, which have identical structures and sandwich the alignment sensor 26 in the X direction. One imperfect shot region exposure system 40A includes an optical member 41, which emits exposure light ILA guided from a light source via a light guide, a condenser optical system 42, which illuminates an irradiated plane with exposure light ILA, a reticle 43, which is arranged along an irradiated plane and serves as a field stop, a mirror 44, which deflects the light from the reticle 43, and a projection system 45, which forms an image 63X (refer to FIG. 4(C)) of a line and space pattern (hereinafter referred to as L & S pattern) that is formed in the reticle 43 in a rectangular exposure region 46A (refer to FIG. 2), which is elongated in the X direction, on the wafer W2 (or W1) held on the wafer stage WST2 (or WST1).

The exposure light ILA has the same wavelength (193 nm) as the exposure light IL (in the present embodiment, ArF excimer laser light) used to expose a wafer with the projection optical system PL. However, as will be described later, the resolution of the imperfect shot region exposure system 40A may be several times to several tens of times lower than the resolution of the projection optical system PL, which employs the liquid immersion technique. Accordingly, ArF excimer laser light having a greater wavelength width than the exposure light IL may be used as the exposure light ILA. This enables the illuminance (pulse energy) of the exposure light ILA to be increased. Thus, sufficient illuminance can be obtained even if the plurality of imperfect shot region exposure systems 40A to 40D, which will be described later, commonly share the light source of the exposure light ILA. Further, the resist on the wafers W1 and W2 are sensitive to ArF excimer laser light. However, if the resist is sensitive to KrF excimer laser light (wavelength 248 nm) or the like, KrF excimer laser light or the like having a longer wavelength than the exposure light IL may be used as the exposure light ILA. This reduces the cost of the light source for the imperfect shot region exposure system 40A.

The other imperfect shot region exposure system 40B has the same structure as the imperfect shot region exposure system 40A and is arranged facing toward the imperfect shot region exposure system 40A in a symmetric manner. Referring to FIG. 2, the imperfect shot region exposure system 40B projects the image of an L & S pattern onto a rectangular exposure region 46B that is symmetric to the exposure region 46A relative to the alignment sensor 26. Further, as shown in FIG. 2, a drive mechanism 47B moves the imperfect shot region exposure system 40B (and ultimately the exposure region 46B) within a predetermined range (for example, the width of one shot region in a wafer) in the X direction relative to a frame (not shown). The drive mechanism 47B, which is controlled by the second control system 20B of FIG. 1, is, for example, of a feed screw type and includes a linear encoder, which monitors the drive amount of the imperfect shot region exposure system 40B. The positioning accuracy of the patterns exposed by the imperfect shot region exposure systems 40A and 40B is only required to be smaller than the width of a scribe line region (for example, 50 nm) between shot regions on the wafer. Thus, the measurement accuracy of the linear encoder may be about 1 μm.

Further, in FIG. 2, at positions obtained by pivoting the imperfect shot region exposure systems 40A and 40B by 90° about the alignment sensor 26 so as to sandwich the alignment sensor 26 in the Y direction, two other imperfect shot region exposure systems 40C and 40D are supported by frames (not shown). The imperfect shot region exposure systems 40C and 40D each have the same structure as the imperfect shot region exposure system 40A and project onto rectangular exposure regions 46C and 46D that are elongated in the Y direction an image 63Y (refer to FIG. 4(D)) of a L & S pattern having a predetermined cycle in the Y direction. Further, a drive mechanism 47D moves the imperfect shot region exposure system 40D (and ultimately the exposure region 46D) within a predetermined range (for example, the width of one shot region in a wafer) in the Y direction relative to a frame (not shown).

The X direction width dX (refer to FIG. 4(A)) of the exposure regions 46A and 46B in the imperfect shot region exposure systems 40A and 40B and the Y direction width dY of the exposure regions 46C and 46C in the imperfect shot region exposure systems 40C and 40D are each smaller than the X direction width of the exposure region 31 of the projection optical system PL (substantially equal to the X direction width of the shot regions on a wafer). However, the size of the exposure regions 46A to 46D may be about the same as the exposure region 31 to increase the exposure efficiency of imperfect shot regions. The present embodiment includes the plurality of (four in FIG. 2) shot region exposure systems 40A to 40D. This increases the exposure efficiency of imperfect shot regions. However, there may be only one imperfect shot region exposure system (for example, only the imperfect shot region exposure system 40A).

One example of the layout of shot regions on a wafer exposed by the exposure apparatus 100 of the present embodiment shown in FIG. 1 will now be described with reference to FIGS. 4(A) to 4(D).

FIG. 4(A) is a plan view showing the wafer W2 on the second wafer stage WST2 of FIG. 1. In FIG. 4(A), the wafer W2 has an exposure surface divided in the X direction and Y direction into a plurality of shot regions SA each having an X direction width DX and a Y direction width DY. The boundary portions between two adjacent shot regions SA each includes a scribe line region SLA having a width of about 50 μm. In one example, circuit formation has been completed in a first layer of the wafer W2, and a two dimensional wafer mark WM, which serves as a fine alignment mark, and a two-dimensional search alignment mark WMS are formed in each shot region. In the present embodiment, as one example, two search alignment marks WMS1 and WMS2 on the wafer W2 on the wafer W2 are detected to determine the position of the wafer W2 in the X direction and Y direction and the rotational angle of the wafer W2 in the θZ direction (search alignment). Then, the positions of the wafer marks WM, which are added to each of a predetermined number (in FIG. 4(A), ten) of shot regions (hereinafter, referred to as sample shot regions) SA1 to SA10, are detected to perform alignment of the wafer W2 in accordance with the EGA technique.

In the exposure surface of the wafer W2, a device region 65D, which includes only perfect shot regions SA that are completely included in the effective exposure region, is defined by the portion surrounded by the solid polygonal line. A non-device region 65ND, which includes only imperfect shot regions (for example, imperfect shot regions SAD1 and SAD2) partially arranged outside the effective exposure region, is defined at the outer side the boundary line 65. The non-device region 65ND includes four non-device regions 66A, 66B, 66C, and 66D, which have simple shapes, and four non-device regions 67A, 67B, 67C, and 67D, which have complicated shapes. The non-device regions 66A, 66B, 66C and 66D are surrounded by a line parallel to the scribe line regions SLA of the wafer W2 (lines parallel to the Y axis and the X axis, for example, a line including a boundary portion 65a) and the rim of the wafer W2. The non-device regions 67A, 67B, 67C, and 67D are surrounded by a boundary portion formed along a boundary line (for example, a boundary portion 65e) and the rim of the wafer W2.

Further, as shown in FIG. 4(B), an image 62X of an L & S pattern having a cycle PX in the X direction or an image 62Y of an L & S pattern having a cycle PY in the Y direction is exposed substantially on the entire surface of each shot region SA in the device region 65D of the wafer W2 by the projection optical system PL of FIG. 1. The cycles PX and PY are determined by values close to the resolution limit of the projection optical system PL. In this case, when a chemical and mechanical polishing (CMP) process is performed in a subsequent stage, it is preferred that the image of an L & S pattern having the same cyclicality (the cycle may be rough) or density as the image 62X or 62Y be exposed on the non-device region 65ND of the wafer W2.

In one example, an image 64X of an L & S pattern having a cycle QX in the X direction as shown in FIG. 4(C) or an image 64Y of an L & S pattern having a cycle QY in the Y direction as shown in FIG. 4(D) is exposed onto the four non-device regions 66A to 66D that have simple shapes in the non-device region 65ND. Thus, the imperfect shot region exposure systems 40A to 40D project an image 63X of an L & S pattern having a cycle QX in the X direction as shown in FIG. 4(C) or an image 63Y of an L & S pattern having a cycle QY in the Y direction as shown in FIG. 4(D) respectively on the rectangular exposure regions 46C and 46D. During exposure of the shot regions, while irradiating the exposure regions 46A and 46B or 46C and 46D shown in FIG. 4(A) with the exposure light ILA, the second wafer stage WST2 scans the wafer W2 in the Y direction or X direction to expose the image 64X or 64Y of an L & S pattern onto the non-device regions 66A to 66D through the scanning exposure technique.

The cycles QX and QY of the images 64X and 64Y are respectively about five to twenty times greater than the cycles PX and PY of the L & S pattern images 62X and 62Y shown in FIG. 4(B) and exposed on the complete shot regions SA. Further, the line widths of line portions (bright portions) in the images 62X and 62Y are substantially one half the cycles QX and QY. Thus, the line widths of line portions (bright portions) in the images 64X and 64Y are five to twenty times greater than the line widths of the line portions (bright portions) in the images 62X and 62Y. When a fine resolution can be provided for the imperfect shot region exposure systems 40A to 40D, the line width of the L & S pattern exposed onto the non-device regions 66A to 66D may be less than the afore-mentioned five times. Further, when problems do not occur during the CMP process, an L & S image exposed onto the non-device regions 66A to 66D may be greater than the afore-mentioned twenty times.

The image of a pattern of the reticle R is exposed onto the four non-device regions 67A to 67D having complicated shapes in the non-device region 65ND by the projection optical system PL of FIG. 1. In this manner, by separating the exposure of the non-device region 65ND between the shot region exposure systems 40A to 40D and the projection optical system PL, the exposure time of the wafer may be reduced in total.

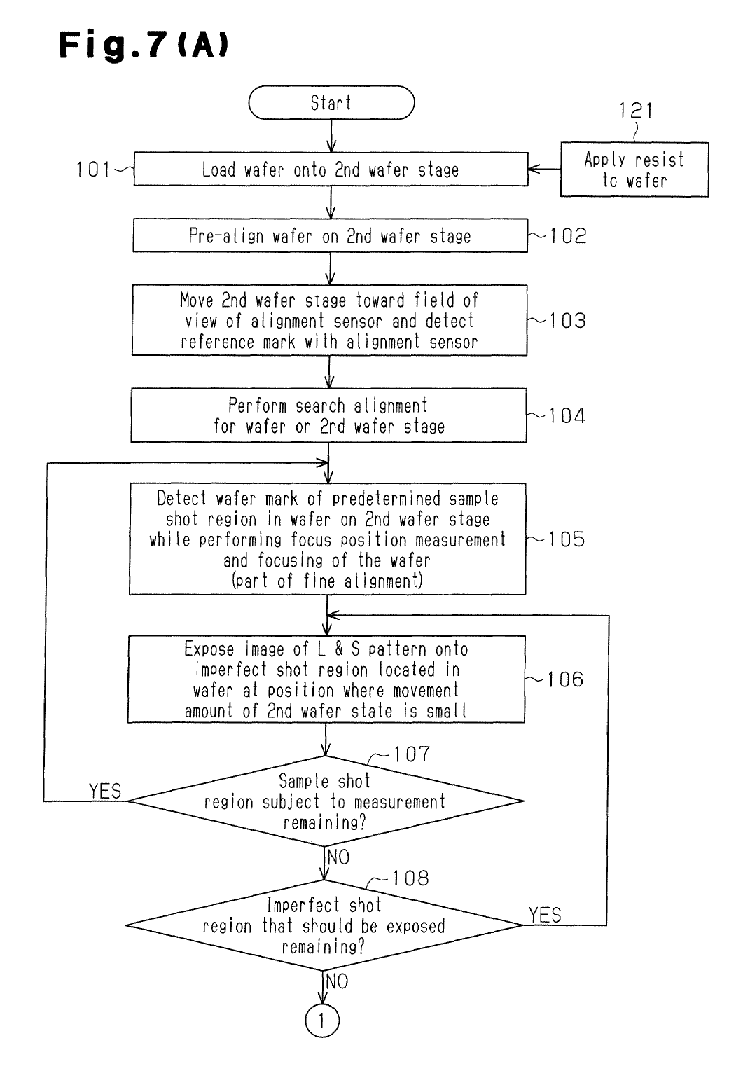

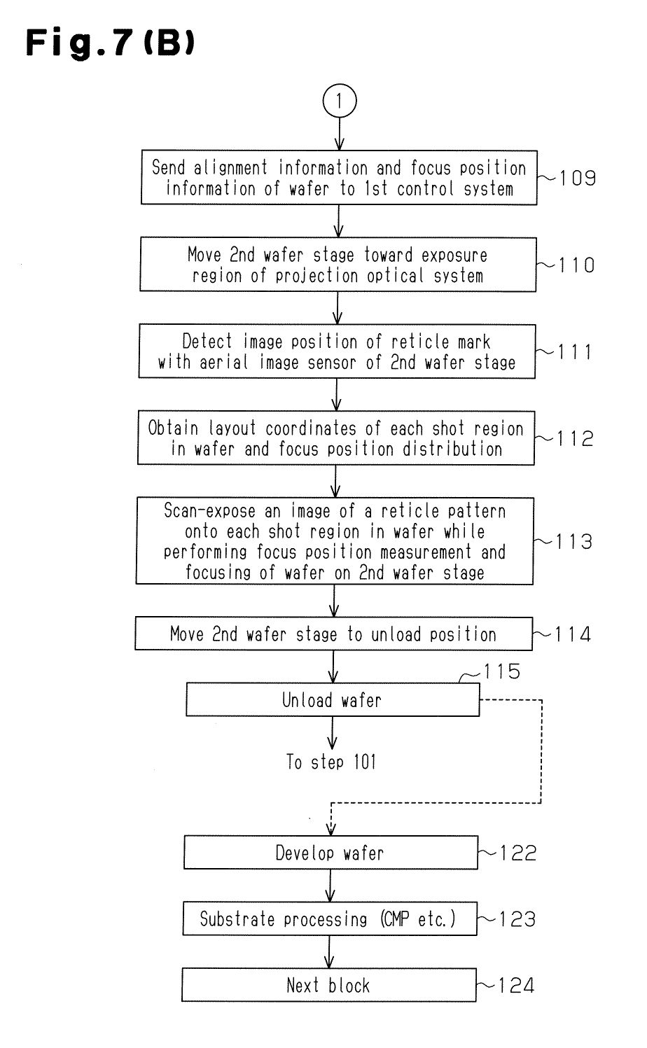

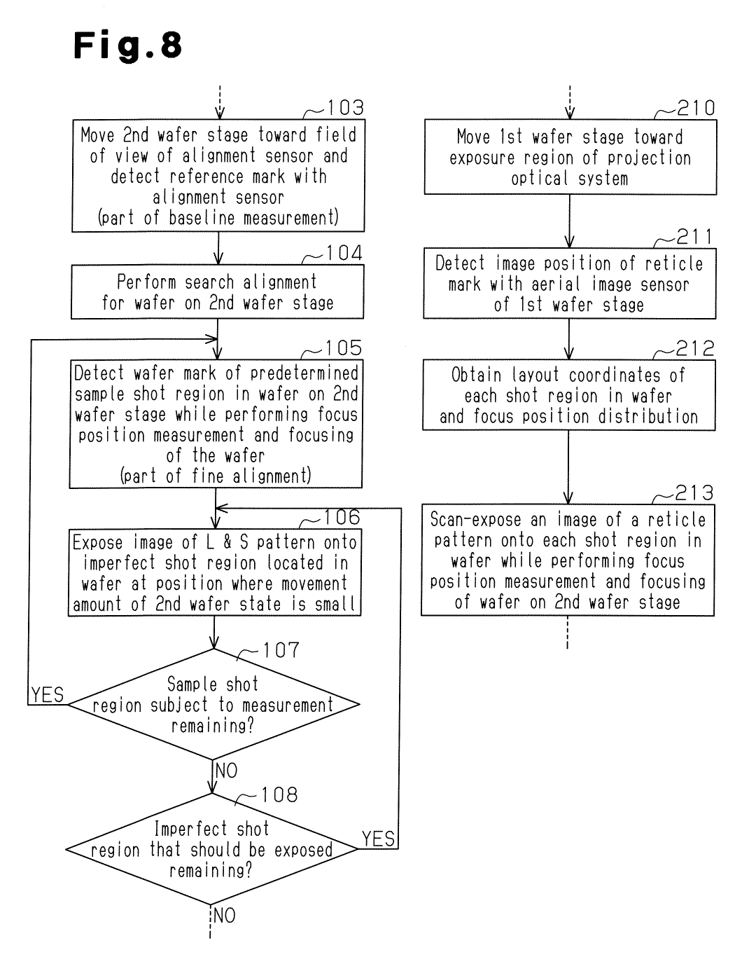

One example of the exposure operation performed by the exposure apparatus 100 of FIG. 1 will now be discussed with reference to the flowcharts of FIGS. 7(A), 7(B) and 8. The operations of steps 101 to 109 and steps 114 and 115 of FIGS. 7(A) and 7(B) are mainly controlled by the second control system 20B, and the operations of steps 110 to 113 of FIG. 7(B) and steps 210 to 213 of FIG. 8 are mainly controlled by the first control system 20A. In the state of FIG. 2 in which the wafer W1 is loaded onto the first wafer stage WST1, in step 101 of FIG. 7(A), the second wafer stage WST2 is moved so that the center of the second wafer stage WST2 is aligned with the loading position LP2 of FIG. 2. Then, the wafer W2 is loaded onto the second wafer stage WST2. Prior to the loading, a coat developer (not shown) applies resist to the wafer W2 (step 121).

Next, in step 102, pre-alignment of the wafer W2 is performed using the PA sensors 48A to 48C of FIG. 2 to detect the position and rotational angle of a profile reference for the wafer W2 on the second wafer stage WST2. This enables the search alignment mark WMS of each shot region SA in the wafer W2 of FIG. 4(A) to be included in the field of view of the alignment sensor 26. If pre-alignment of the wafer W is performed in a wafer loader system (not shown), step 102 can be eliminated. Then, in step 103, the second wafer stage WST2 is moved to the field of view of the alignment sensor 26, and the alignment sensor 26 detects the reference mark 53B shown in FIG. 2 (part of the baseline measurement).

In this case, for example, the aerial image measurement system 55B of the wafer stage WST2 that is shown in FIG. 2 is used beforehand to measure the positions of the exposure regions 46A to 46D in the imperfect shot region exposure systems 40A to 40C. The positional relationship between the detection center of the alignment sensor 26 and the index mark of the aerial image measurement system 55B can be determined from the known distance between the reference mark 53B and the index mark of the aerial image measurement system 55B. Accordingly, the positional relationship between each shot region (including imperfect shot regions) in the wafer W2 and the imperfect shot region exposure systems 40A to 40C can be determined. From this stage, the focus position measurement of the wafer W2 and detected surface by the AF system 29 of FIG. 1, and the focusing of the alignment sensor 26 on a detected mark based on the measurement results are performed.

Next in step 104, for example, the magnification of the alignment sensor 26 is lowered to widen the field of view, detect the two search alignment marks WMS1 and WMS2 on the wafer W2 of FIG. 4(A), and obtain the X direction and Y direction offsets of the shot region alignment in the wafer W2, and the rotational angle in the θZ direction. The search alignment enables the position of the non-device region 65ND on the wafer W2 to be recognized with an accuracy that is smaller than the width of the scribe line region SLA. Further, the search alignment causes the wafer mark WM in each shot region SA of the wafer W2 to be included in the high magnification field of view of the alignment sensor 26 shown in FIG. 2.

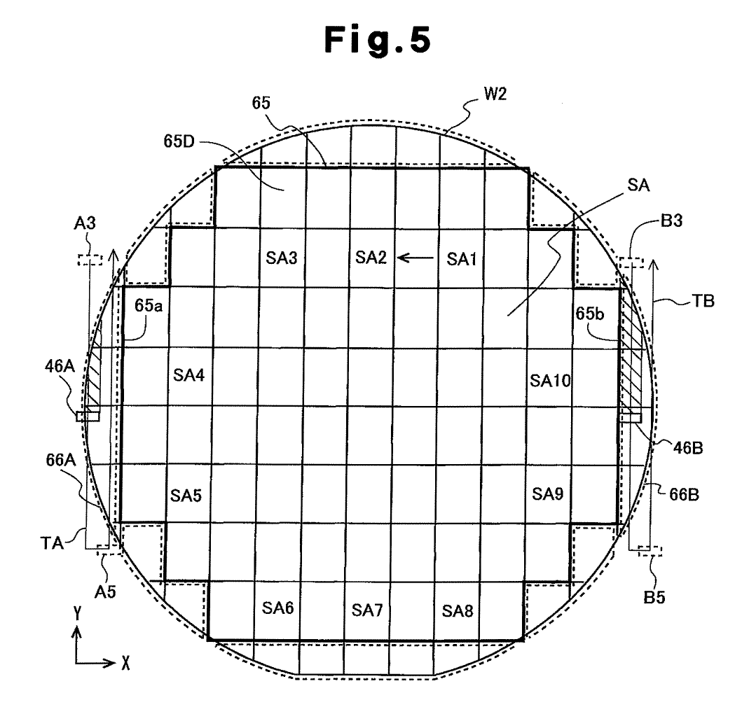

Then, in step 105, referring to FIG. 5, the wafer marks of the two sample shot regions SA1 and SA2 on the wafer W2 are detected (part of fine alignment) by the alignment sensor 26 of FIG. 1, while the AF system 29 performs focus position measurement on the surface of the wafer W2 and the alignment sensor 26 performs focusing on the detected mark. In a state in which measurement of the sample shot region SA2 is completed in this manner, the exposure regions 46A and 46B of the imperfect shot region exposure systems 40A and 40B (in this state, the exposure light ILA is not emitted) are located in the vicinity of the positions A3 and B3, which are preferable for exposing the non-device regions 66A and 66B of FIG. 5 (the movement amount of the second wafer stage WST2 can be small).

Thus, in step 106, the second drive mechanism 47B finely moves the imperfect shot region exposure system 40B in the X direction and sets the sum of the X direction width of the device region 65D and the width of the exposure region 46A as the X direction distance between the exposure regions 46A and 46B of FIG. 5. Then, the −X direction edge of the exposure region 46B is aligned with the boundary portion 65b in the +X direction of the device region 65D. Subsequently, the second wafer stage WST2 is positioned so that the exposure regions 46A and 46B are arranged at positions A3 and B3. Further, the emission of the exposure light ILA to the exposure regions 46A and 46B is started. After scanning the second wafer stage WST2 in the +Y direction, the second wafer stage WST2 is step-moved in the −X direction by an amount corresponding to the width of the exposure region 46A to move the exposure regions 46A and 46B to positions A5 and B5. By scanning the second wafer stage WST2 in the −Y direction, the exposure regions 46A and 46B relatively move in the non-device regions 66A and 66B as shown by tracks TA and TB in FIG. 5 (the edge of the exposure region 46A moves in the boundary portion 65a of the device region 65D). Thus, the L & S pattern image 64X of FIG. 4(C) is exposed in the non-device regions 66A and 66B.

Meanwhile, the history of measurement values or the actual measurement values obtained in real time of the focus position of the wafer W2 taken by the AF system 29 of FIG. 1 obtains information on the focus position in the surface of the wafer W2 that is closest to the exposure regions 46A and 46B. Based on this information, the Z position and leveling of the Z-leveling stage 35B in the second wafer state WST2 are controlled so that each projection system 45 (refer to FIG. 1) of the imperfect shot region exposure systems 40A and 40B are focused on the surface of the wafer W2. The projection system 45 has a longer focal depth than the projection optical system PL. Thus, the control described above obtains the necessary focusing accuracy.

When the X direction width of the non-device regions 66A and 66B is narrow, the exposure regions 46A and 46B may be entirely exposed just by once relatively scanning the exposure regions 46A and 46B and the wafer W2 in the Y direction.

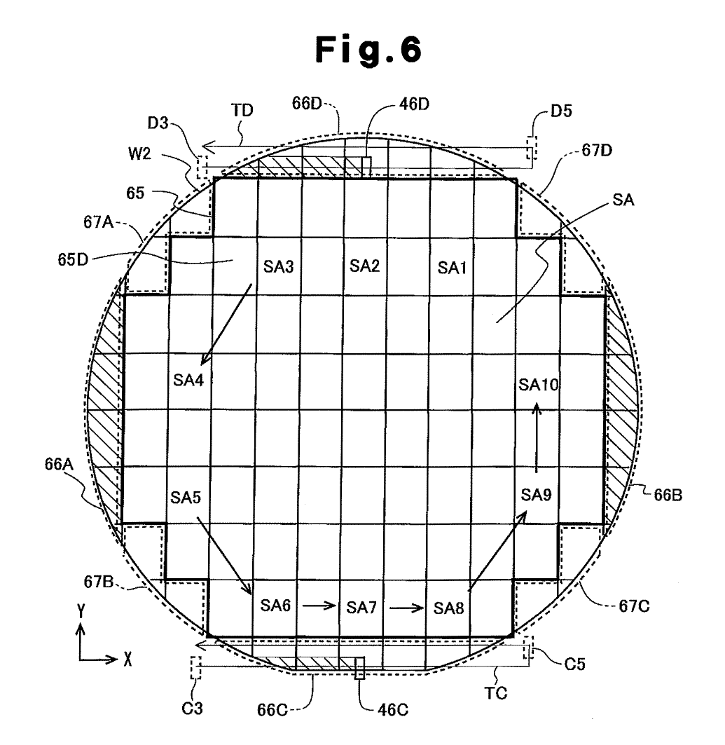

In this state, the field of view of the alignment sensor 26 of FIG. 2 is located on the sample shot region SA2. Thus, in step 107, it is determined whether there still remains a sample shot region that is subject to measurements. At this stage, the sample shot regions SA3 to SA10 are still remaining. Thus, the processing returns to step 105, and the alignment sensor 26 detects the wafer marks on the two sample shot regions SA3 and SA4 shown in FIG. 6. In this state, the exposure regions 46C and 46D of the imperfect shot region exposure systems 40C and 40D are located in the vicinity of positions C3 and D3, which are preferable for exposing the non-device regions 66C and 66D of FIG. 6 (the movement amount of the second wafer stage WST2 can be small).

Then, proceeding to step 106, the second drive mechanism 47D drives the imperfect shot region exposure system 40D in the Y direction and sets the sum of the Y direction width of the device region 65D and the width of the exposure region 46C as the Y direction distance between the exposure regions 46C and 46D of FIG. 6. Then, the −Y direction edge of the exposure region 46D is aligned with the boundary portion 65b in the +Y direction of the device region 65D, and the exposure regions 46C and 46D are arranged at positions C3 and D3. Further, the emission of the exposure light ILA to the exposure regions 46C and 46D is started. After scanning the second wafer stage WST2 in the −Y direction, the second wafer stage WST2 is step-moved in the −Y direction by an amount corresponding to the width of the exposure region 46C to move the exposure regions 46C and 46D to positions C5 and D5. By scanning the second wafer stage WST2 in the +X direction, the exposure regions 46C and 46D move in the non-device regions 66C and 66D as shown by tracks TC and TD in FIG. 6. Thus, the L & S pattern image 64X of FIG. 4(D) is exposed in the non-device regions 66C and 66D. In this state, the field of view of the alignment sensor 26 is located in the vicinity of the sample shot region SA5 of the wafer W2 shown in FIG. 6.

In step 107, the sample shot regions SA5 to SA10 are still remaining in this state. Thus, the processing returns to step 105, and the alignment sensor 26 detects the wafer marks on the remaining sample shot regions SA5 to SA10 shown in FIG. 6. In this state, there are no non-device regions that are to be exposed by the imperfect shot region exposure systems 40A to 40D. Further, there are no sample shot regions that are to be exposed by the shot region exposure systems 40A to 40D. Thus, the processing proceeds from step 106 to step 107. Further, since there are no sample shot regions that are to be measured by the imperfect shot region exposure systems 40A to 40D, the processing proceeds to step 108 in which it is finally determined whether there are remaining non-device regions (imperfect shot regions) that should be exposed by the shot region exposure systems 40A to 40D. When there is a non-device region that should be exposed, the processing returns to step 106.

In step 108, if there are no non-device regions that should be exposed, the processing proceeds to step 109, and the second control system 20B of FIG. 1 calculates the layout coordinates of each shot region in the wafer W2 (alignment information) using the reference mark 53B of FIG. 2 in accordance with, for example, the EGA technique. Further, the second control system 20B obtains the distribution information of the focus position on the surface of the wafer W2 (focus position information) from the measurement value obtained by the AF system 29 during alignment. The alignment information and focus position information of the wafer W2 is sent from the second control system 20B to the first control system 20A.

Then, in step 110 of FIG. 7(B), the second wafer stage WST2 moves along the path MP2 toward the exposure region side of the projection optical system PL. In parallel with this movement, the first wafer state WST1 moves along the path MP1 toward the field of view of the alignment sensor 26. Then, at position LP1, the wafer than has undergone exposure on the first wafer stage WST1 is exchanged with a non-exposed wafer W3.

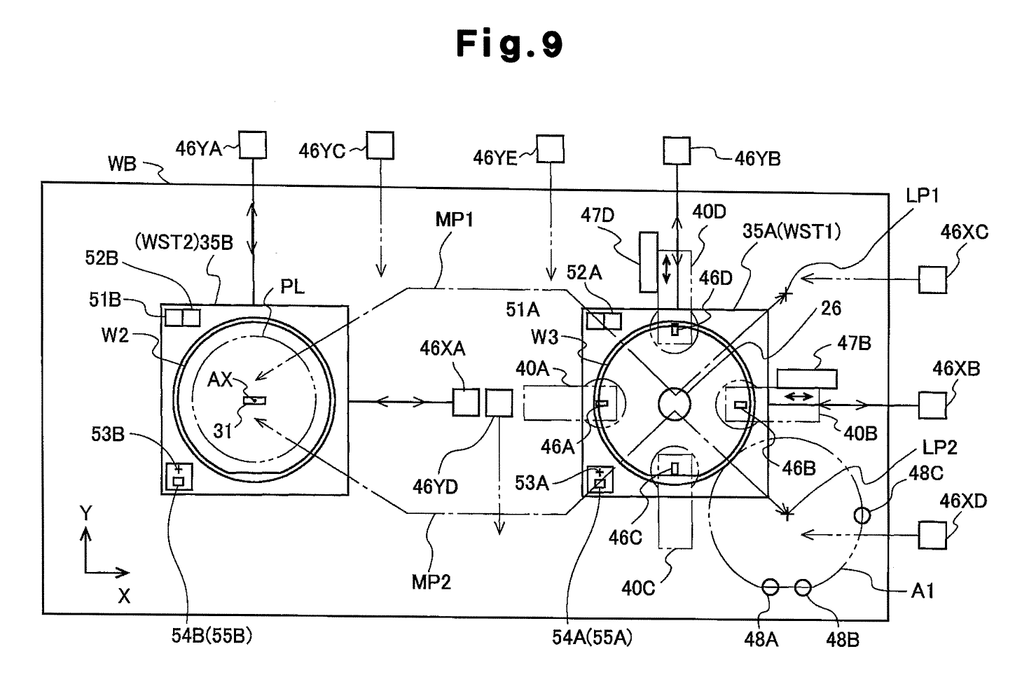

In step 111, the aerial image measurement system 55B of the wafer stage WST2 shown in FIG. 9 detects the image position of the reticle mark of the reticle R shown in FIG. 1 (base line measurement). Next, in step 112, the first control system 20A uses the image position and the known positional relationship reference mark 53B and the light receiving window 54B to convert the layout coordinates of each shot region in the wafer W2 provided from the second control system 20B into layout coordinates that are based on the image of the reticle. Subsequently, the converted layout coordinates are used to align each shot region in the wafer W2 and an image of the reticle R with high accuracy.

Further, the first control system 20A measures a single focus position (defocus amount of the projection optical system PL with respect to the image plane) on the wafer W2 with, for example, the AF system 28. Then, the first control system 20A uses the measurement values to convert the distribution information of the focus position on the wafer W2 provided from the second control system 20B to the distribution of the defocus amount from the image plane of the projection optical system PL. Subsequently, the Z-leveling stage 35B is driven beforehand to align the surface of the exposure region 31 in the wafer W2 with the image plane. This reduces the defocus amount and enables the focusing with the measurement values of the AF system 28 to be performed at higher speeds and with higher accuracy.

Then, in step 113, while performing focus position measurement and focusing on the wafer W2 that is held on the second wafer state WST2, the image of a pattern of the reticle R is scanned and exposed onto each shot region of the wafer W2 using the liquid immersion technique. In the present embodiment, the image (images 62X and 62Y of FIG. 4(B)) of a pattern of the reticle R is exposed onto each imperfect shot region in the four non-device regions 67A to 67D of the non-device shown in FIG. 4(A). More specifically, the wafer stage WST2 of FIG. 9 is driven in the X direction and Y direction to step-move the wafer W2 to a scanning initiation position. Then, the supply of liquid Lq to the liquid immersion region 30 shown in FIG. 1 and the emission of the exposure light IL are started. Further, in synchronism with the scanning of the reticle R in the Y direction with the reticle stage RST, scanning exposure is performed on the exposure region 31 in a direction corresponding to one shot region of the wafer W2 with the wafer stage WST2 of FIG. 9 using the projection magnification as a speed ratio. A step-and-scan operation that repeats the step movement and the scan exposure transfers the image of a pattern of the reticle R onto the shot regions of the device region 65D and the non-device regions 67A to 67D in the non-device region 65ND on the wafer W2 of FIG. 4(A).

Next, in step 114, as shown in FIG. 2, the second wafer stage WST2 is moved to the unloading position LP2. In step 115, the wafer W2 is unloaded. The processing then proceeds to step 101 in which the next wafer is loaded. The exposed wafer W2 unloaded in step 115 is transferred from the exposure apparatus 100 to the coater developer (not shown), and, in step 122, the resist on the wafer is developed. Then, in step 123, substrate processing, which includes heating (curing) of the developed wafer, an etching process, and a CMP process, is performed. Next, in step 124, after repeating lithography and substrate processing as required, device assembling (processing including dicing, bonding, and packaging) and inspection are performed to complete the manufacture of a device such as a semiconductor device. The image of the L & S pattern having a predetermined cyclicality is exposed onto substantially the entire exposure surface of the wafer W2, and the development and substrate processing forms a pattern having the cyclicality on substantially the entire surface of the wafer. This enables the CMP process to be easily performed.

An operation, which is similar to the exposure operation performed on the wafer W2 on the second wafer stage WST2 in steps 101 to 115 of FIGS. 7(A) and 7(B), is performed in parallel on the wafer W1 on the first wafer stage WST1. However, as shown in FIG. 8, at the same time as the alignment and imperfect shot region exposure operation of the wafer W2 on the second wafer stage WST2 in steps 103 to 108, the exposure of the image of a pattern of the reticle R with the projection optical system PL is performed on the wafer W1 on the first wafer stage WST1 in steps 210 to 213. Conversely, when the alignment and imperfect shot region exposure corresponding to steps 105 to 108 are performed on the wafer on the first wafer stage WST1, the exposure performed with the projection optical system PL on the wafer on the second wafer stage WST2 in steps 110 to 113 is simultaneously performed.

Advantages and modifications of the present embodiment will now be discussed.

(1) In the exposure method performed with the exposure apparatus 100 of FIG. 1, a plurality of regions on the wafer shown in FIG. 4(A) including a region (first region) defined by the device region 65D and a region (second region) defined by the non-device region 65ND are performed. The exposure method includes step 105 performed parallel to an operation (step 213) for exposing with the projection optical system PL (first optical system) the first region of the wafer W1 held on the first wafer stage WST1 (first substrate movable holder) that moves along a guide plane (two-dimensional plane). In step 105, the search alignment marks WMS1 and WMS2 of the wafer W2 on the second wafer stage WST2 (second substrate movable holder), which moves along the guide plane, are detected. The exposure method also includes steps 105 to 108 in which an operation for exposing with the imperfect shot region exposure systems 40A to 40D (second optical system) the second region of the wafer W2 on the second wafer stage WST2 based on the detection results of the search alignment marks WMS1 and WMS2 is substantially performed in parallel with an operation for detecting the wafer marks WM added to the sample shot regions SA1 to SA10 of the wafer W2. Further, the exposure method includes step 113 in which exposure is performed with the projection optical system PL on the first region of the wafer W2 on the second wafer stage WST2 based on the detection result of the wafer mark WM.

Further, the exposure apparatus 100 includes the first wafer stage WST1, the second wafer stage WST2, the alignment sensor 26 that detects at least either one of the reference mark 53B on the second wafer stage WST2 and the marks of the wafers on the wafer stages WST1 and WST2, the projection optical system PL that irradiates the first region of a wafer with the exposure light IL, and the imperfect shot region exposure systems 40A to 40D that irradiates the second region, which differs from the first region, of the wafer with the exposure light ILA. During the operation in which the projection optical system PL irradiates the wafer W1, which is held on the first wafer stage WST1, the alignment sensor 26 detects the reference mark 53B on the second wafer stage WST2 or the marks of the wafer W2. Further, during the operation in which the alignment sensor 26 detects the marks, the imperfect shot region exposure systems 40A to 40D irradiates the second region of the wafer W2 held on the second wafer stage WST2 with the exposure light ILA.

The present embodiment substantially performs in parallel exposure of the first region (region including perfect shot regions) of the wafer W1 on the first wafer stage WST1 and exposure of the second region (region including imperfect shot regions) of the wafer W2. Thus, patterns respectively corresponding to the first and second regions of the wafers W1 and W2 are effectively exposed. Further, the mark detection performed by the alignment sensor 26 (mark detection operation of step 105) to perform exposure on the first region of the wafer W2 is performed substantially parallel to the exposure of the second region of the wafer W2 (step 106). This further improves throughput of the exposure process.

(2) Further, in FIG. 4(A), the surface of the wafer W2 is divided into the device region 65D, which includes a plurality of complete shot regions (partitioned regions), and the non-device region 65ND, which includes a plurality of partially imperfect shot regions. The first region of the wafer W2 includes the device region 65D and part of the non-device region 65ND (the non-device regions 67A to 67D having complicated shapes). The second region of the wafer W2 includes the regions of the non-device region 65ND that are not included in the first region (the non-device regions 66A to 66D having simple shapes). As a result, in the non-device region 65ND (imperfect shot regions), the regions included in the first region are exposed by the projection optical system PL, and the second region is exposed by the imperfect shot region exposure systems 40A to 40D. In such a manner, the throughput of the exposure process is improved by dividing the exposure of imperfect shot regions.

For example, if there are many shot region exposure systems 40A to 40D or if the time for alignment and imperfect shot region exposure performed on the wafer W1 by the alignment sensor 26 and the imperfect shot region exposure systems 40A to 40D is shorter than the time for exposure performed on the wafer W1 by the projection optical system PL of FIG. 1, the non-device region 65ND of the wafer W2 may be completely exposed by the imperfect shot region exposure systems 40A to 40D.

(3) In FIG. 4(A), the second region (non-device regions 66A to 66D) of the wafer W2 is a region having a simple shape and surrounded by a line parallel to either one of two orthogonal directions and the rim of the wafer W2. Thus, the images 64X and 64Y of the patterns of FIGS. 4(C) and 4(D) can be efficiently exposed through, for example, the scan exposure technique by using the imperfect shot region exposure systems 40A to 40D of FIG. 2 on the second region.

(4) After the alignment sensor 26 detects at least two (search alignment marks WMS1 and WMS2) of the plurality of marks of the wafer W2 on the second wafer stage WST2 (step 104), the imperfect shot region exposure systems 40A to 40D irradiate the second region of the wafer W2 with the exposure light ILA (step 106). In this case, the position of the second region may be recognized with the required accuracy by using the detection result of step 104.

In FIG. 4(A), for example, if the pre-alignment accuracy is high, the detection operation of the search alignment marks WMS1 and WMS2 (step 104) may be eliminated. In such a case, the positions of the wafer marks (fine alignment marks) of two sample shot regions (for example, SA1 and SA2) in the wafer W2 are detected to recognize the position of the non-device region 65ND. Accordingly, the second region is exposed with the imperfect shot region exposure systems 40A to 40D after detecting the wafer marks of the two sample shot regions.

(5) After the imperfect shot region exposure systems 40A to 40D start irradiating the non-device regions 66A and 66B in the second region (first step 106), the alignment sensor 26 starts detection of wafer marks, which differ from the at least two marks, from the sample shot region SA3 (second step 105). Thus, the positioning for imperfect shot region exposure and the positioning for fine alignment may both use the results of the search alignment.

(6) The wafer stage control unit 21B controls the position of the second wafer stage WST2 on a guide plane. The wafer stage control unit 21B moves the second wafer stage WST2 based on the detection information of the at least two search alignment marks WMS1 and WMS2. By using the detection information of the search alignment marks WMS1 and WMS2, subsequent marks can be included in the field of view of the alignment sensor 26.

(7) The projection optical system PL exposes the L & S pattern images 62X and 62Y (first pattern) of FIG. 4(B) onto the first region of a wafer, and the imperfect shot region exposure systems 40A to 40D expose the L & S pattern images 64X and 64Y (second pattern), which differ from the first pattern, onto the second region of the wafer. This enables the resolution of the imperfect shot region exposure systems 40A to 40D to be lower than the resolution of the projection optical system PL. Thus, for example, when performing liquid immersion exposure with the projection optical system PL, the imperfect shot exposure systems 40A to 40D may perform dry exposure. Accordingly, the structure of the imperfect shot region exposure systems 40A to 40D can be simplified.

(8) When the line width of the images 64X and 64Y is five to twenty times greater than the minimum line width of the images 62X and 62Y, the imperfect shot region exposure systems 40A to 40D can be simplified and the subsequently performed CMP process can be performed in a satisfactory manner.

The exposure of a specific pattern does not have to be performed on the non-device region 65ND of FIG. 4(A), and the imperfect shot region exposure systems 40A to 40D may perform exposure with only a predetermined amount of exposure light that exceeds the resist sensitivity (the so-called peripheral exposure).

(9) The AF system 29 (surface position detection unit) detects the focus position (surface position information) along the normal direction (Z direction) of the guide plane for the wafer W2 held on the second wafer stage WST2. The distance between the wafer W2 held on the second wafer stage WST2 and the imperfect shot region exposure systems 40A to 40D is controlled based on the surface position information detected by the AF system 29. This enables imperfect shot region exposure to be performed with a high resolution.

Instead of the commonly shared AF system 29 shown in FIG. 1, a compact AF system (autofocus sensor) having few measurement points may be provided for each of the imperfect shot region exposure systems 40A to 40D. In such a case, the information of the focus position on a wafer measured by each AF system may be used to accurately perform focusing with the corresponding imperfect shot region exposure system and measure distribution information of the focus position on the surface of the wafer in advance.

(10) The drive mechanism (adjustment unit) 47B (or 47D) adjusts the distance between two imperfect shot region exposure systems (exposure units) 40A and 40B (or 40C and 40D) of the plurality of imperfect shot region exposure systems 40A to 40D.

The distance between the imperfect shot region exposure systems 40A and 40B is adjusted in accordance with the shot region layout of the wafer W2 by the drive mechanism 47B. Thus, as shown in FIG. 5, the two imperfect shot region exposure systems 40A and 40B can expose the second region of the wafer simultaneously and in parallel. Accordingly, the imperfect shot region exposure can be performed further efficiently.

(11) The position detected by the alignment sensor 26 of FIG. 2 is located in the area surrounded by the exposure regions 46A to 46D of the plurality of imperfect shot region exposure systems 40A to 40D. This enables the alignment and imperfect shot region exposure to be efficiently performed.

(12) In the above-described embodiment, the imperfect shot region exposure systems 40A to 40D and the wafer W2 are relatively moved while the imperfect shot region exposure systems 40A to 40D irradiate the exposure regions 46At to 46D (part of the second region) on the wafer W2 with exposure light IL2. That is, the scanning exposure technique efficiently performs continuous exposure of an image of the predetermined L & S pattern on the series of imperfect shot regions in, for example, the wafer W2. In this case, it is only required that the image of the L & S pattern be performed. Thus, the reticle 43 (refer to FIG. 1) in each of the imperfect shot region exposure systems 40A to 40D is only required to include an L & S pattern having a predetermined cycle in the non-scanning direction, and a scanning mechanism for the reticle 43 is not necessary.

The imperfect shot region exposure systems 40A to 40D expose the wafer W2 through the step-and-repeat technique.

(13) The projection optical system PL performs exposure with the liquid Lq between the projection optical system PL and the wafer, and the imperfect shot region exposure systems 40A to 40D perform exposure by carrying out dry exposure.

(14) It is preferable that the wavelength of the exposure light IL be substantially the same as the wavelength of the exposure light ILA. This sensitizes the resist on a wafer through the imperfect shot region exposure within a short period of time.

The light source that supplies the exposure light IL as an exposure beam may be the same as the light source that supplies the exposure light ILA for performing imperfect shot region exposure.

Further, a light guide is used to guide the exposure light ILA from the light source to the imperfect shot region exposure systems 40A to 40D. However, a transmission optical system formed by lens and the like can be used in lieu of the light guide to guide the exposure light ILA from the light source to the imperfect shot region exposure systems 40A to 40D.

(15) The device manufacturing method of the above-described embodiment includes a process for preparing a wafer (photosensitive substrate) to which resist is applied (step 121), a process for exposing a predetermined pattern onto the wafer with the projection optical system PL and the imperfect shot region exposure systems 40A to 40D (steps 101 to 115), a process for developing the exposed wafer and forming on the surface of the wafer a mask layer having a shape corresponding to the exposed pattern (step 122), and a process for processing the surface of the wafer through the mask layer (step 123).

In this case, the exposure apparatus 100 efficiently exposes the wafer including the imperfect shot regions, and a CMP process can be subsequently performed in a satisfactory manner. Thus, devices can be manufactured with a high yield and high throughput.

The present invention is applicable not only to a scanning exposure type projection exposure apparatus but also to a batch exposure type (stepper type) projection exposure apparatus. Further, the present invention may be applied when performing exposure with a dry exposure type exposure apparatus.

Further, the application of the present invention is not limited to a process for manufacturing semiconductor devices and may be widely applied to a process for manufacturing a display device such as a liquid crystal display device formed on a polygonal glass plate or a process for manufacturing various types of devices such as an imaging device (CCD or the like), a micro-machine, a microelectromechanical system (MEMS), a thin film magnetic head, a DNA chip, and the like.

The present invention is not limited to the foregoing embodiments and various changes and modifications of its components may be made without departing from the scope of the present invention.

What is claimed is:

1. An exposure method for exposing a plurality of regions including different first and second regions of a substrate, the exposure method comprising:
exposing a first region of a first substrate, which is held on a first substrate movable holder that moves along a two-dimensional plane, with a first optical system, and, in parallel, detecting a predetermined mark from a plurality of predetermined marks on a second substrate movable holder that moves along the two-dimensional plane or on a second substrate held by the second substrate movable holder;
exposing a second region of the second substrate, which is held on the second substrate movable holder, with a second optical system based on the detection result of the predetermined mark, and, in parallel, detecting a mark excluding the predetermined mark from the plurality of marks; and
exposing a first region of the second substrate, which is held on the second substrate movable holder, with the first optical system based on the detection results of the plurality of marks.

2. The exposure method according to claim 1, wherein:
the second substrate includes a surface divided into a plurality of perfect partitioned regions and a plurality of partially imperfect partitioned regions;
the first region of the second substrate includes the plurality of perfect partitioned regions and some of the plurality of partially imperfect partitioned regions; and
the second region of the second substrate includes the partially imperfect partitioned regions that are excluded from the first region.

3. The exposure method according to claim 2, wherein the second region of the second substrate is surrounded by a straight line parallel to one of two orthogonal directions and a rim of the second substrate.

4. The exposure method according to claim 1, wherein:
the first optical system exposes a first pattern onto the first region of each substrate;
the second optical system exposes a second pattern onto the second region of each substrate; and
the second pattern has a line width that is five to twenty times greater than a minimum line width of the first pattern.

5. The exposure method according to claim 1, wherein the first exposure system uses first exposure light and the second optical system uses second exposure light, with the second exposure light having a wavelength width that is greater than that of the first exposure light.

6. The exposure method according to claim 1, wherein the second substrate and the second optical system are relatively moved while the second optical system exposes part of the second region of the second substrate.

7. An exposure apparatus for exposing a plurality of regions of a substrate, the exposure apparatus comprising:
a first substrate movable holder which holds a substrate and is movable along a two-dimensional plane;
a second substrate movable holder which holds a substrate and is movable along the two-dimensional plane;
an alignment system which detects at least either marks on the two substrate movable holders or marks on the substrates held by the two substrate movable holders;
a first optical system which irradiates a first region of a substrate with first exposure light; and
a second optical system which irradiates a second region of a substrate that differs from the first region with second exposure light;
wherein the alignment system detects a mark on the second substrate movable holder or the second substrate held, which is held by the second substrate movable holder when the first optical system irradiates the first substrate, which is held by the first substrate movable holder, with the first exposure light; and
the second optical system irradiates the second region of the second substrate, which is held by the second substrate movable holder, with the second exposure light when the alignment system is detecting the mark.

8. The exposure apparatus according to claim 7, wherein the second optical system irradiates the second region of the second substrate with the second exposure light after detecting at least two of the plurality of marks on the second substrate, which is held by the second substrate movable holder.

9. The exposure apparatus according to claim 8, wherein the alignment system starts detecting a mark in the plurality of marks that differs from the at least two marks after the second optical system starts to irradiate the second region with the exposure light.

10. The exposure apparatus according to claim 8, further comprising:
a position control unit which controls the position of the second substrate movable holder on the two-dimensional plane, with the position control unit moving the second substrate movable holder based on detection information of the at least two marks.

11. The exposure apparatus according to claim 7, wherein:
the first optical system exposes a first pattern onto the first region; and
the second optical system exposes a second pattern, which differs from the first pattern, onto the second region.

12. The exposure apparatus according to claim 11, wherein the second pattern has a line width that is five to twenty times greater than a minimum line width of the first pattern.

13. The exposure apparatus according to claim 7, further comprising:
a surface position detection unit which detects surface position information along a normal direction of the two-dimensional plane of the second substrate held by the second substrate movable holder;
wherein distance between the second substrate, which is held by the second substrate movable holder, and the second optical system is controlled based on the surface position information detected by the surface position detection unit.

14. The exposure apparatus according to claim 7, wherein the second optical system includes a plurality of exposure units respectively irradiating a plurality of the second regions of the second substrate.

15. The exposure apparatus according to claim 14, further comprising:
an adjustment unit which adjusts the distance between two of the plurality of exposure units in the second optical system.

16. The exposure apparatus according to claim 14, wherein the alignment system performs detection at a position surrounded by a plurality of positions irradiated with the second exposure light by the plurality of exposure units in the second optical system.

17. The exposure apparatus according to claim 7, wherein the second substrate and the second optical system are relatively moved while the second optical system irradiates part of the second region of the second substrate with the second exposure light.

18. The exposure apparatus according to claim 7, wherein the second region is surrounded by the first region in the substrate.

19. The exposure apparatus according to claim 18, wherein the second region is surrounded by a straight line parallel to one of two orthogonal directions and a rim of the substrate.

20. The exposure apparatus according to claim 19, wherein:
the first region is exposed through liquid arranged between the first optical system and a substrate; and
the second region is exposed without through liquid arranged between the second optical system and a substrate.

21. The exposure apparatus according to claim 7, wherein the first exposure light used to expose the first region has a wavelength that is substantially the same as that of the second exposure light.

22. A method for manufacturing a device, the method comprising:
preparing a photosensitive substrate;
using the exposure apparatus according to claim 7 to expose a predetermined pattern onto the photosensitive substrate with the first and second optical systems;
developing the exposed photosensitive substrate to form on a surface of the photosensitive substrate a mask layer having a shape corresponding to the pattern exposed by the first and second optical systems; and
processing the surface of the photosensitive substrate through the mask layer.
